(19) United States
(12) Patent Application Publication
(10) Pub. No.: US 2012/0091541 A1
(43) Pub. Date: Apr. 19, 2012

(54) MIXED METAL OXIDES

(75) Inventors: Matthew Suchomel, Argonne, IL (US); Matthew Rosseinsky, Cheshire (GB); Hongjun Niu, Merseyside (GB); Paul Raymond Chalker, Cheshire (GB); Lei Yan, Merseyside (GB)

(73) Assignee: The University of Liverpool, Liverpool (GB)

(21) Appl. No.: 13/262,977

(22) PCT Filed: Apr. 7, 2010
(86) PCT No.: PCT/GB2010/050599

§ 371 Date: Dec. 16, 2011

(30) Foreign Application Priority Data
Apr. 8, 2009 (GB) 0906105.2

(51) Int. Cl. H01L 29/78; H01L 21/31; C04B 35/49; H01L 29/02

(52) U.S. Cl. 257/411; 257/632; 438/785; 501/136; 257/E29.002; 257/E29.255; 257/E21.24

(57) ABSTRACT

The present invention relates to a mixed metal oxide of formula SrM1-xTixO3 wherein x is 0>x>1 and M is Hf or Zr, such as a strontium-hafnium-titanium oxide orstrontium-zirconium-titanium oxide, and to a functional device comprising the mixed metal oxide.

The present invention relates to a mixed metal (strontium-titanium) oxide such as a strontium-hafnium-titanium and strontium-zirconium-titanium oxide, to a functional device comprising the mixed metal oxide, to its use as a dielectric (eg a high-k dielectric) as or in an electrical, electronic, magnetic, mechanical, optical or thermal device and to a process for preparing a functional device comprising the mixed metal oxide.

The silicon dioxide (SiO₂) gate layer in a MOS (metal-oxide-semiconductor) field effect transistor device may be substituted by an oxide material with a higher dielectric constant (high-k). However there are few oxide materials which satisfy the requirements of dielectric constant, thermal stability and band gap, whilst providing an interface suitable for integration by silicon processing (see J Robertson, J. Appl. Phys. 104, 7 (2008)). These oxides include ZrO₂ (see M N S Miyazaki et al, Microelectronic Engineering 59, 6 (2001) and R N Wen-Jie Qi et al, Appl. Phys. Lett. 77, 3 (2000)), HfO₂ (see T M R C Smith et al, Adv. Mater. Opt. Electron. 10, 10 (2000); E C E P Gusev et al, Microelectronic Engineering 59, 9 (2001); and R H D C Gilmer et al, Appl. Phys. Lett. 81, 3 (2002)), Al₂O₃ (see E C M Copel et al, Appl. Phys. Lett. 78, 3 (2001) and C P E Ghiraldelli et al, Thin Solid Films 517, 3 (2008)) and LaAlO₃ (see S K Seung-Gu Lim et al, J. Appl. Phys. 91, 6 (2002); H B L L Yan, et al, Appl. Phys. A 77, 4 (2003); and H L Wenfeng Xiang et al, J. Appl. Phys. 93, 4 (2003)).

Due to its high dielectric constant (˜35) and large band gap (˜6.2 eV), SrHfO₃ is attracting increasing interest as a candidate for a high-k material (B M C Rossel et al, Appl. Phys. Lett. 89, 3 (2006); G K G Lupina et al, Appl. Phys. Lett. 93, 3 (2008) and C R M Sousa et al, J. Appl. Phys. 102, 6 (2007)). SrTiO₃ and Sr₁₋ₓBaₓTiO₃ are attractive candidates for a gate dielectric because of their large permittivity. However the low conduction band offset due to the relatively low energy of the 3d Ti states is unfavourable for Si-based electronics.

EP-A-568064 discloses the use of a non-stoichiometric mixed phase layer containing strontium, hafnium and titanium (a buffer layer) to ameliorate the effects of lattice mismatching and chemical interaction between a germanium layer and a layer of Bi₄Ti₃O₁₂.

The present invention seeks to exploit the high lying 5d states of Hf or the high lying 4d states of Zr by the introduction of Hf or Zr respectively into SrTiO₃ to increase the band gap. This is achieved without compromising the high k value.

Thus viewed from a first aspect the present invention provides a mixed metal oxide of formula:

SrM₁₋ₓTiₓO₃

wherein x is 0<x<1; and

M is Hf or Zr.

By retaining the high permittivity attributable to Ti—O bonding and exploiting the high lying 5d states of Hf or the high lying 4d states of Zr to enhance the band gap (and therefore the conduction band offset to Si), strontium-hafnium-titanium and strontium-zirconium-titanium oxides according to the present invention represent excellent candidates for a high dielectric material for use in a silicon based integrated circuit.

In a preferred embodiment, M is Hf.

In a preferred embodiment, M is Zr.

Preferably 0.01<x<0.99, particularly preferably 0.05≦x≦0.95, more particularly preferably 0.2≦x≦0.8, yet more particularly preferably 0.3≦x≦0.7, even more preferably 0.4≦x≦0.6, yet even more preferably 0.45≦x≦0.55. In a preferred embodiment, x is about 0.5.

In a preferred embodiment, the mixed metal oxide (in the form of a bulk material) exhibits a dielectric constant (typically at 10 kHz) of greater than 35, preferably a dielectric constant in the range 36 to 200, particularly preferably in the range 45 to 125, more preferably in the range 60 to 100.

In a preferred embodiment, the mixed metal oxide (in the form of a bulk material) exhibits a band gap of 3.10 eV or more, preferably a band gap in the range 3.10 to 6.10 eV, particularly preferably in the range 3.24 to 3.80 eV, more preferably in the range 3.40 to 3.50 eV.

The mixed metal oxides of the present invention may be prepared by high temperature solid state reaction, a sol-gel process, PVD, aerosol-assisted deposition, flame deposition, spin coating, sputtering, CVD (eg MOCVD), ALD, MBE or PLD.

The high dielectric constant and band gap of the mixed metal oxides of the present invention may be exploited in electrical, electronic or optical applications. For example, the mixed metal oxides of the present invention may be useful as a gate dielectric in a field effect transistor device (eg a MOSFET device) or in a high frequency dielectric application. For example, the mixed metal oxides of the present invention may be used as or in a capacitor (eg in a memory device such as DRAM or RAM), a voltage regulator, an electronic signal filter, a microelectromechanical device, a sensor, an actuator, a display (eg a TFT or OLED), a solar cell, a charged couple device, a particle and radiation detector, a printed circuit board, a CMOS device, an optical fibre or an optical waveguide. For example, the mixed metal oxides of the present invention may be used as an optical fibre or in an optical waveguide.

The mixed metal oxide of the present invention may be present in a multiphase composition. Preferably the mixed metal oxide is substantially monophasic.

Viewed from a further aspect the present invention provides a composition comprising a mixed metal oxide as hereinbefore defined and one or more oxides of one or more of strontium, M and titanium.

The one or more oxides of one or more of strontium, M and titanium may be simple oxides or mixed metal oxides. The one or more oxides of one or more of strontium, M and titanium may be SrTiO₃, ZrTiO₃ or HfTiO₃.

Viewed from a yet further aspect the present invention provides a functional device comprising:
a substrate; and
an element fabricated on the substrate, wherein the element is composed of a mixed metal oxide or composition thereof as hereinbefore defined

The functional device may be an electrical, electronic, magnetic, mechanical, optical or thermal device.

The substrate may be a layer. The element may be a layer or thin film.

The substrate may be a semiconductor such as an oxide semiconductor, an organic semiconductor, a III-V semiconductor (eg GaAs, InGaAs, TiN, GaN or InGaN), a II-VI semiconductor (eg ZnSe or CdTe) or a transparent conducting oxide (eg Al:ZnO, indium tin oxide or fluoride-doped tin oxide).

The substrate may be (or contain) silicon, doped silicon or silicon dioxide. Typically the substrate is silicon.

The substrate may be selected from the group consisting of germanium, silicon, silicon dioxide, doped silicon, GaAs, InGaAs, GaN, InGaN, ZnSe, CdTe, ZnO, TiN, Al:ZnO, indium tin oxide or fluoride-doped tin oxide.

The substrate may be an electronic substrate which may comprise one or more electronic parts, devices or structures (eg a printed circuit board).

The substrate may be conductive. For example, the substrate may a conductive mixed metal oxide such as a metal-doped metal oxide (eg Nb doped SrTiO₃).

An electrode may be placed on or applied to (eg deposited on) the element. The electrode may be composed of an elemental metal or metal alloy. For example, the electrode may be (or contain) tantalum, titanium, gold or platinum.

In a preferred embodiment, the functional device is a field effect transistor device wherein the substrate is a substrate layer and the element is a gate dielectric fabricated on the substrate layer, wherein the field effect transistor further comprises:
a gate on the gate dielectric.

Preferably the field effect transistor device is a MOSFET device. The field effect transistor device may be present in a CPU or GPU.

The gate dielectric is typically a gate dielectric layer. The thickness of the gate dielectric layer may be 3.0 nm or more. The gate dielectric layer may be deposited on the substrate layer. For example, the gate dielectric layer may be deposited epitaxially on the substrate layer.

Viewed from a still further aspect the present invention provides use of a mixed metal oxide or composition thereof as hereinbefore defined as a dielectric (eg a high-k dielectric) as or in an electrical, electronic, magnetic, mechanical, optical or thermal device.

Preferably the use is in a field effect transistor device. The field effect transistor device may be present in a CPU or GPU.

Preferably the use is as or in a capacitor (eg in a memory device such as DRAM or RAM), a voltage regulator, an electronic signal filter, a microelectromechanical device, a sensor, an actuator, a display (eg a TFT or OLED), a solar cell, a charged couple device, a particle and radiation detector, a printed circuit board, a CMOS device, an optical fibre or an optical waveguide.

Viewed from a yet still further aspect the present invention provides a process for preparing a functional device as hereinbefore defined comprising:
exposing discrete volatilised amounts of a strontium precursor, a hafnium or zirconium precursor and a titanium precursor to the substrate in sequential exposure steps in a contained environment.

Each discrete volatilised amount may be fed to the contained environment in one or more pulses. The pulse length may be in the range 1 ms to 30 s.

Preferably the process further comprises:
feeding an oxidising agent to the contained environment during one or more exposure steps or in one or more intervals between the exposure steps.

The oxidising agent may be fed into the contained environment continuously during the exposure steps. The oxidising agent may be fed into the contained environment by one or more pulses (eg in one or more intervals between the exposure steps).

The oxidising agent may be selected from the group consisting of oxygen (eg oxygen plasma), water vapor, hydrogen peroxide (or an aqueous solution thereof), ozone, an oxide of nitrogen (such as N₂O, NO or NO₂), a halide-oxygen compound (for example chlorine dioxide or perchloric acid), a peracid (for example perbenzoic acid or peracetic acid), an alcohol (such as methanol or ethanol) and radicals (such as oxygen radicals and hydroxyl radicals).

Preferably the process further comprises:
purging the contained environment in intervals between the sequential exposure steps.

The contained environment may be purged in steps which alternate with the sequential exposure steps. Purging may be carried out by an inert gas flow.

Preferably the sequential exposure steps are cyclical. The number and order of each of the steps of exposing discrete volatilised amounts of a strontium precursor, a hafnium or zirconium precursor and a titanium precursor to the substrate in the sequential exposure steps may be empirically determined to achieve a desired stoichiometry and incorporation rate. The number of cycles is determined by the desired oxide thickness. Typically the sequential exposure steps are cycled 2 to 100 times.

Preferably the process of the invention comprises a cycle of sequential exposure steps (A), (B) and (C), wherein
step (A) comprises: feeding the discrete volatilised amount of strontium precursor into the contained environment and purging the strontium precursor from the contained environment,
step (B) comprises: feeding the discrete volatilised amount of hafnium or zirconium precursor into the contained environment and purging the hafnium or zirconium precursor from the contained environment,
step (C) comprises: feeding the discrete volatilised amount of a titanium precursor into the contained environment and purging the titanium precursor from the contained environment.

Each of steps (A), (B) and (C) may be cyclical. Preferably the ratio of the number of cycles in step (B) to the number of cycles in step (C) is in the range 1:1 to 1:3.

Particularly preferably the process of the invention comprises a cycle of sequential exposure steps (A′), (B′) and (C′), wherein
step (A′) comprises: feeding the discrete volatilised amount of strontium precursor into the contained environment, purging the strontium precursor from the contained environment, feeding an oxidising agent into the contained environment and purging the contained environment,
step (B′) comprises: feeding the discrete volatilised amount of hafnium or zirconium precursor into the contained environment, purging the hafnium or zirconium precursor from the contained environment, feeding an oxidising agent into the contained environment and purging the contained environment,
step (C′) comprises: feeding the discrete volatilised amount of a titanium precursor into the contained environment, purging the titanium precursor from the contained environment, feeding an oxidising agent into the contained environment and purging the contained environment.

Each of steps (A′), (B′) and (C′) may be cyclical. Preferably the ratio of the number of cycles in step (B′) to the number of cycles in step (C′) is in the range 1:1 to 1:3.

The contained environment is typically a reaction chamber.

Each precursor may be a volatile liquid or solid, a solid dissolvable or suspendable in a solvent medium for flash vaporization or a sublimable solid. Volatilsation of the precursor may be heat-assisted or photo-assisted. Each discrete volatilised amount may be fed into the contained environment in the gaseous phase (eg as a vapour). The contained environment may be at a temperature in the range 100 to 700° C., preferably 150 to 500° C.

The process may further comprise: pre-treating (eg pre-heating) the substrate.

The process may further comprise: a post-treatment step. The post-treatment step may be a post-annealing (eg rapid thermal post-annealing) step, oxidizing step or reducing step. The step of post-annealing is typically carried out at a temperature in excess of the temperature at which the sequential steps are carried out in the contained environment. For example, post-annealing may be carried out at a temperature in the range 500° C. to 900° C. for an annealing period of a few seconds to 60 minutes in an air flow.

Each precursor may be a complex featuring one or more bonds between the metal and each of one or more organic ligands (eg coordination bonds between the metal and a heteroatom such as oxygen or nitrogen or bonds between the metal and carbon). The precursor may be a metal organic or an organometallic complex.

The titanium precursor may be a titanium (III) or titanium (IV) precursor. The titanium precursor may be a titanium halide, titanium β-diketonate, titanium alkoxide (such as iso-propoxide or tert-butoxide), dialkylamino titanium complex, alkylamino titanium complex, silylamido titanium complex, cyclopentadienyl titanium complex, titanium dialkyldithiocarbamate or titanium nitrate.

The titanium of the titanium precursor may have one or more (for example four) organic ligands which may be the same or different selected from the group of organic ligands defined by formulae (I) to (IV) (preferably one of formulae (I) to (IV)) as follows:

[R¹C(O)—CH—C(O)R²]⁻ (I)

(wherein each of R¹ and R² which may be the same or different is an optionally fluorinated, linear or branched C₁₋₁₂ alkyl group);

[X(R³)_{w}(R⁴)_{y}(R⁵)_{z}] (II)

(wherein X is a heteroatom;

R³ is H or an optionally fluorinated, linear or branched C₁₋₁₂ alkyl group optionally substituted by one or more alkoxy, amino, alkylamino or dialkylamino groups or a Si(R⁶)₂ or Si(R⁶)₃ group;

R⁴ is H or an optionally fluorinated, linear or branched C₁₋₁₂ alkyl group optionally substituted by one or more alkoxy, amino, alkylamino or dialkylamino groups or a Si(R⁷)₂ or Si(R⁷)₃ group;

R⁵ is H or an optionally fluorinated, linear or branched C₁₋₁₂ alkyl group optionally substituted by one or more alkoxy, amino, alkylamino or dialkylamino groups or a Si(R⁸)₂ or Si(R⁸)₃ group;

each of R⁶, R⁷ and R⁸ is independently H or a linear or branched C₁₋₁₂ alkyl, C₆₋₁₂ aryl, C₃₋₁₂ allyl or C₃₋₁₂ vinyl group optionally substituted by one or more alkoxy, amino, alkylamino or dialkylamino groups;

w is an integer of 1 or 2;

y is an integer of 0 or 1; and

z is an integer of 0 or 1);

[S₂CN(R⁹)(R¹⁰)] (III)

(wherein each of R⁹ and R¹⁰ is independently an optionally fluorinated, linear or branched C₁₋₁₂ alkyl group optionally substituted by one or more alkoxy, amino, alkylamino or dialkylamino groups);

[Cp] (IV)

(wherein Cp denotes a single or fused cyclopentadiene moiety optionally ring-substituted partially or fully by one or more of the group consisting of an optionally substituted, acyclic or cyclic, linear or branched alkyl, alkenyl, aryl, alkylaryl, aralkyl or alkoxy group or a thio, amino, cyano or silyl group).

Preferably the titanium of the titanium precursor has four organic ligands selected from the group of organic ligands defined by formulae (I) to (IV) (preferably one of formulae (I) to (IV)).

Preferably the ligand of formula (I) is an optionally methylated and/or optionally fluorinated (eg optionally tri- or hexa-fluorinated) acetylacetonato, heptanedionato or octanedionato ligand. For example, the ligand of formula (I) may be a 1,1,1-trifluoropentane-2,4-dionato, 1,1,1,5,5,5-hexafluoropentane-2,4-dionato or 2,2,6,6-tetramethyl-3,5-heptanedionato ligand.

Preferably either or both of R¹ and R² are trifluorinated or hexafluorinated.

Preferably R¹ is a C₁₋₆ perfluoroalkyl. Preferably R² is a C₁₋₆ perfluoroalkyl.

Preferably X is O. Particularly preferably X is O, y is 0, z is 0, w is 1 and R³ is an optionally fluorinated, linear or branched C₁₋₁₂ alkyl group optionally substituted by one or more alkoxy, amino, alkylamino or dialkylamino groups. For example, the ligand of formula (II) may be a hexafluoroisopropoxy, 2-dimethylaminoethanolate, 2-methoxyethanolate or 1-methoxy-2-methyl-2-propanolate ligand.

Preferably X is N. Particularly preferably X is N, y is 1, w is 1, z is 1 and each of R³, R⁴ and R⁵ is independently H, an optionally fluorinated, linear or branched C₁₋₁₂ alkyl group optionally substituted by one or more alkoxy, amino, alkylamino or dialkylamino groups.

Alternatively particularly preferably, X is N, y is 1, w is 1, z is 1, R³ is Si(R⁶)₂ or Si(R⁶)₃ , R⁴ is Si(R⁷)₂ or Si(R⁷)₃ and R⁵ is Si(R⁸)₂ or Si(R⁸)₃, wherein each of R⁶, R⁷ and R⁸ is independently methyl, propyl or butyl.

Preferably each of R³, R⁴ and R⁵ is independently methyl, ethyl, propyl, butyl or pentyl, particularly preferably methyl, propyl or butyl, more preferably n-butyl, tert-butyl, iso-propyl or ethyl.

Preferably the titanium of the titanium precursor has two ligands of formula (IV). The cyclopentadiene moieties of the two ligands of formula (IV) may be bridged. The bridge may be a substituted or unsubstituted C₁₋₆-alkylene group which is optionally interrupted by a heteroatom (such as O, Si, N, P, Se or S).

Preferably the ligand of formula (IV) is a cyclopentadienyl, indenyl, fluorenyl, pentamethylcyclopentadienyl, tert-butylcyclopentadienyl or triisopropylcyclopentadienyl ligand.

Preferably in a titanium precursor the (or each) ligand of formula (IV) is a cyclopentadienyl ligand of formula (V)

[C₅(R¹¹)ₘH₅₋ₘ] (V)

(wherein m is an integer in the range 0 to 5 and

each R¹¹ which may be the same or different is selected from the group consisting of a C₁₋₁₂ alkyl, C₁₋₁₂ alkylamino, C₁₋₁₂ dialkylamino, C₁₋₁₂ alkoxy, C₃₋₁₀ cycloalkyl, C₂₋₁₂ alkenyl, C₇₋₁₂ aralkyl, C₇₋₁₂ alkylaryl, C₆₋₁₂ aryl, C₅₋₁₂ heteroaryl, C₁₋₁₀ perfluoroalkyl, silyl, alkylsilyl, perfluoroalkylsilyl, triarylsilyl and alkylsilylsilyl group).

Preferably the (or each) R¹¹ group is methyl, ethyl, propyl (eg isopropyl) or butyl (eg tert-butyl).

The titanium precursor may be Ti(OC₂H₅)₄, Ti(OⁱPr)₄, Ti(O^{t}Pr)₄, Ti(OⁿBu)₄ or Ti(OCH₂(C₂H₅)CHC₄H₉)₄.

The titanium precursor may be titanium nitrate.

The titanium precursor may be di(iso-propoxy)bis(2,2,6,6-tetramethyl-3,5-heptanedionato) titanium or tris(2,2,6,6,-tetramethyl-3,5-heptanedionato) titanium or adducts or hydrates thereof.

The titanium precursor may be tetrakis(diethylamido) titanium, tetrakis(dimethylamido) titanium, tetrakis(ethylmethylamido) titanium, tetrakis(isopropylmethylamido) titanium, bis(diethylamido)bis(dimethylamido) titanium, bis(cyclopentadienyl)bis(dimethylamido) titanium, tris(dimethylamido)(N,N,N′-trimethylethyldiamido) titanium or tert-butyltris(dimethylamido) titanium or adducts or hydrates thereof.

The titanium precursor may be titanium (η⁵-O₅H₅)₂, titanium (η⁵-C₅H₅)(η⁷-C₇H₇), (η⁵-C₅H₅) titanium Z₂ (wherein Z is alkyl (eg methyl), benzyl or carbonyl), bis(tertbutylcyclopentadienyl) titanium dichloride, bis(pentamethylcyclopentadienyl) titanium dichloride or (C₅H₅)₂ titanium (CO)₂ or adducts or hydrates thereof.

The titanium precursor may be a titaniumdialkyldithiocarbamate.

The titanium precursor may be TiCl₄, TiCl₃, TiBr₃, TiI₄ or TiI₃.

The hafnium precursor may be a hafnium (IV) precursor. The hafnium precursor may be a hafnium β-diketonate, hafnium alkoxide, dialkylamino hafnium complex, alkylamino hafnium complex or cyclopentadienyl hafnium complex.

The hafnium of the hafnium precursor may have one or more (for example four) organic ligands which may be the same or different selected from the group of organic ligands defined by formulae (VI) to (VIII) (preferably one of formulae (VI) to (VIII)) as follows:

[R¹²C(O)—CH—C(O)R¹³]⁻ (VI)

(wherein each of R¹² and R¹³ which may be the same or different is an optionally fluorinated, linear or branched C₁₋₁₂ alkyl group);

[X(R¹⁴)_{w}(R¹⁵)_{y}(R¹⁶)_{z}] (VII)

(wherein X is a heteroatom;

R¹⁴ is H or an optionally fluorinated, linear or branched C₁₋₁₂ alkyl group optionally substituted by one or more alkoxy, amino, alkylamino or dialkylamino groups or a (SiR¹⁷)₂ or (SiR¹⁷)₃ group;

R¹⁵ is H or an optionally fluorinated, linear or branched C₁₋₁₂ alkyl group optionally substituted by one or more alkoxy, amino, alkylamino or dialkylamino groups or a (SiR¹⁸)₂ or (SiR¹⁸)₃ group;

R¹⁶ is H or an optionally fluorinated, linear or branched C₁₋₁₂ alkyl group optionally substituted by one or more alkoxy, amino, alkylamino or dialkylamino groups or a (SiR¹⁹)₂ or (SiR¹⁹)₃ group;

each of R¹⁷, R¹⁸ and R¹⁹ is independently H or a linear or branched C₁₋₁₂ alkyl, C₆₋₁₂ aryl, C₃₋₁₂ allyl or C₃₋₁₂ vinyl group optionally substituted by one or more alkoxy, amino, alkylamino or dialkylamino groups;

w is an integer of 1 or 2;

y is an integer of 0 or 1; and

z is an integer of 0 or 1);

[Cp] (VIII)

(wherein Cp denotes a single or fused cyclopentadiene moiety optionally ring-substituted partially or fully by one or more of the group consisting of an optionally substituted, acyclic or cyclic, linear or branched alkyl, alkenyl, aryl, alkylaryl, aralkyl or alkoxy group or a thio, amino, cyano or silyl group).

Preferably the hafnium of the hafnium precursor has four organic ligands selected from the group of organic ligands defined by formulae (VI) to (VIII) (preferably one of formulae (VI) to (VIII)).

Preferably the ligand of formula (VI) is an optionally methylated and/or optionally fluorinated (eg optionally tri- or hexa-fluorinated) acetylacetonato, heptanedionato or octanedionato ligand. For example, the ligand of formula (VI) may be a 1,1,1-trifluoropentane-2,4-dionato, 1,1,1,5,5,5-hexafluoropentane-2,4-dionato or 2,2,6,6-tetramethyl-3,5-heptanedionato ligand.

Preferably either or both of R¹² and R¹³ are trifluorinated or hexafluorinated.

Preferably R¹² is a C₁₋₆ perfluoroalkyl. Preferably R¹³ is a C₁₋₆ perfluoroalkyl.

Preferably X is O. Particularly preferably X is O, y is 0, w is 1, z is 0 and R¹⁴ is an optionally fluorinated, linear or branched C₁₋₁₂ alkyl group optionally substituted by one or more alkoxy, amino, alkylamino or dialkylamino groups. For example, the ligand of formula (VII) may be an isopropoxy, 2-dimethylaminoethanolate, 2-methoxyethanolate or 1-methoxy-2-methyl-2-propanolate ligand.

Preferably X is N. Particularly preferably X is N, y is 1, w is 1, z is 1 and each of R¹⁴, R¹⁵ and R¹⁶ is independently H or an optionally fluorinated, linear or branched C₁₋₁₂ alkyl group optionally substituted by one or more alkoxy, amino, alkylamino or dialkylamino groups.

Preferably each of R¹⁴, R¹⁵ and R¹⁶ is independently methyl, ethyl, propyl, butyl or pentyl, particularly preferably methyl, propyl or butyl, more preferably n-butyl, tert-butyl, isopropyl or ethyl.

The hafnium of the hafnium precursor may have one or two ligands of formula (VIII).

Preferably the hafnium of the hafnium precursor has two ligands of formula (VIII). The cyclopentadiene moieties of the two ligands of formula (VIII) may be bridged. The bridge may be a substituted or unsubstituted C₁₋₆-alkylene group which is optionally interrupted by a heteroatom (such as O, Si, N, P, Se or S).

Preferably the ligand of formula (VIII) is a cyclopentadienyl, indenyl, fluorenyl, methylcyclopentadienyl, pentamethylcyclopentadienyl or triisopropylcyclopentadienyl ligand.

Preferably in a hafnium precursor the (or each) ligand of formula (VIII) is a cyclopentadienyl ligand of formula (IX)

[C₅(R²⁰)ₘH₅₋ₘ] (IX)

(wherein m is an integer in the range 0 to 5 and

each R²⁰ which may be the same or different is selected from the group consisting of a C₁₋₁₂ alkyl, C₁₋₁₂ alkylamino, C₁₋₁₂ dialkylamino, C₁₋₁₂ alkoxy, C₃₋₁₀ cycloalkyl, C₂₋₁₂ alkenyl, C₇₋₁₂ aralkyl, C₇₋₁₂ alkylaryl, C₆₋₁₂ aryl, C₅₋₁₂ heteroaryl, C₁₋₁₀ perfluoroalkyl, silyl, alkylsilyl, perfluoroalkylsilyl, triarylsilyl and alkylsilylsilyl group).

Preferably the (or each) R²⁰ group is methyl, ethyl, propyl (eg isopropyl) or butyl (eg tert-butyl), particularly preferably methyl.

The hafnium precursor may be di(isopropoxy)bis(2,2,6,6-tetramethyl-3,5-heptanedionato) hafnium.

The hafnium precursor may be bis(methylcyclopentadienyl) dimethylhafnium, bis(methylcyclopentadienyl) methoxymethylhafnium or methylcyclopentadienyl hafnium tris(dimethylamide) or adducts or hydrates thereof.

The hafnium precursor may be tetrakis(dimethylamido) hafnium, tetrakis(diethylamido) hafnium or tetrakis(ethylmethylamido) hafnium or adducts or hydrates thereof.

The hafnium precursor may be hafnium (IV) iso-propoxide, hafnium (IV) tert-butoxide, tetrakis(2-methyl-2-methoxypropoxy) hafnium, bis(isopropoxy)bis(2-methyl-2-methoxypropoxy) hafnium or bis(tert-butoxy)bis(2-methyl-2-methoxypropoxy) hafnium or adducts or hydrates thereof.

The hafnium precursor may be HfCl₄.

The zirconium precursor may be a zirconium (IV) precursor. The zirconium precursor may be a zirconium β-diketonate, zirconium alkoxide, dialkylamino zirconium complex, alkylamino zirconium complex or cyclopentadienyl zirconium complex.

The zirconium of the zirconium precursor may have one or more (for example four) organic ligands which may be the same or different selected from the group of organic ligands defined by formulae (X) to (XII) (preferably one of formulae (X) to (XII)) as follows:

[R²¹C(O)—CH—C(O)R²²]⁻ (X)

(wherein each of R²¹ and R²² which may be the same or different is an optionally fluorinated, linear or branched C₁₋₁₂ alkyl group);

[X(R²³)_{w}(R²⁴)_{y}(R²⁵)_{z}] (XI)

(wherein X is a heteroatom;

R²³ is H or an optionally fluorinated, linear or branched C₁₋₁₂ alkyl group optionally substituted by one or more alkoxy, amino, alkylamino or dialkylamino groups or a (SiR²⁶)₂ or (SiR²⁶)₃ group;

R²⁴ is H or an optionally fluorinated, linear or branched C₁₋₁₂ alkyl group optionally substituted by one or more alkoxy, amino, alkylamino or dialkylamino groups or a (SiR²⁷)₂ or (SiR²⁷)₃ group;

R²⁵ is H or an optionally fluorinated, linear or branched C₁₋₁₂ alkyl group optionally substituted by one or more alkoxy, amino, alkylamino or dialkylamino groups or a (SiR²⁸)₂ or (SiR²⁸)₃ group;

each of R²⁶, R²⁷ and R²⁸ is independently H or a linear or branched C₁₋₁₂ alkyl, C₆₋₁₂ aryl, C₃₋₁₂ allyl or C₃₋₁₂ vinyl group optionally substituted by one or more alkoxy, amino, alkylamino or dialkylamino groups;

w is an integer of 1 or 2;

y is an integer of 0 or 1; and

z is an integer of 0 or 1);

[Cp] (XII)

(wherein Cp denotes a single or fused cyclopentadiene moiety optionally ring-substituted partially or fully by one or more of the group consisting of an optionally substituted, acyclic or cyclic, linear or branched alkyl, alkenyl, aryl, alkylaryl, aralkyl or alkoxy group or a thio, amino, cyano or silyl group).

Preferably the zirconium of the zirconium precursor has four organic ligands selected from the group of organic ligands defined by formulae (X) to (XII) (preferably one of formulae (X) to (XII)).

Preferably the ligand of formula (X) is an optionally methylated and/or optionally fluorinated (eg optionally tri- or hexa-fluorinated) acetylacetonato, heptanedionato or octanedionato ligand. For example, the ligand of formula (X) may be a 1,1,1 -trifluoropentane-2,4-dionato, 1,1,1,5,5,5-hexafluoropentane-2,4-dionato or 2,2,6,6-tetramethyl-3,5 -heptanedionato ligand.

Preferably either or both of R²¹ and R²² are trifluorinated or hexafluorinated.

Preferably R²¹ is a C₁₋₆ perfluoroalkyl. Preferably R²² is a C₁₋₆ perfluoroalkyl.

Preferably X is O. Particularly preferably X is 0, z is O, y is 0, w is 1 and R²³ is an optionally fluorinated, linear or branched C₁₋₁₂ alkyl group optionally substituted by one or more alkoxy, amino, alkylamino or dialkylamino groups. For example, the ligand of formula (XI) may be a isopropoxy, 2-dimethylaminoethanolate, 2-methoxyethanolate or 1-methoxy-2-methyl-2-propanolate ligand.

Preferably X is N. Particularly preferably X is N, y is 1, w is 1, z is 1 and each of R²³, R²⁴ and R²⁵ is independently H or an optionally fluorinated, linear or branched C₁₋₁₂ alkyl group optionally substituted by one or more alkoxy, amino, alkylamino or dialkylamino groups.

Preferably each of R²³, R²⁴ and R²⁵ is independently methyl, ethyl, propyl, butyl or pentyl, particularly preferably methyl, propyl or butyl, more preferably n-butyl, tert-butyl, isopropyl or ethyl.

The zirconium of the zirconium precursor may have one or two ligands of formula (XII).

Preferably the zirconium of the zirconium precursor has two ligands of formula (XII). The cyclopentadiene moieties of the two ligands of formula (XII) may be bridged. The bridge may be a substituted or unsubstituted C₁₋₆-alkylene group which is optionally interrupted by a heteroatom (such as O, Si, N, P, Se or S).

Preferably the ligand of formula (XII) is a cyclopentadienyl, indenyl, fluorenyl, pentamethylcyclopentadienyl or triisopropylcyclopentadienyl ligand.

Preferably in a zirconium precursor the (or each) ligand of formula (XII) is a cyclopentadienyl ligand of formula (XIII)

[C₅(R²⁹)ₘH₅₋ₘ] (XIII)

(wherein m is an integer in the range 0 to 5 and

each R²⁹ which may be the same or different is selected from the group consisting of a C₁₋₁₂ alkyl, C₁₋₁₂ alkylamino, C₁₋₁₂ dialkylamino, C₁₋₁₂ alkoxy, C₃₋₁₀ cycloalkyl, C₂₋₁₂ alkenyl, C₇₋₁₂ aralkyl, C₇₋₁₂ alkylaryl, C₆₋₁₂ aryl, C₅₋₁₂ heteroaryl, C₁₋₁₀ perfluoroalkyl, silyl, alkylsilyl, perfluoroalkylsilyl, triarylsilyl and alkylsilylsilyl group).

Preferably the (or each) R²⁹ group is methyl, ethyl, propyl (eg isopropyl) or butyl (eg tert-butyl), particularly preferably methyl.

The zirconium precursor may be di(isopropoxy)bis(2,2,6,6-tetramethyl-3,5-heptanedionato) zirconium.

The zirconium precursor may be bis(methylcyclopentadienyl) dimethylzirconium, bis(methylcyclopentadienyl) methoxymethylzirconium or methylcyclopentadienyl zirconium tris(dimethylamide) or adducts or hydrates thereof.

The zirconium precursor may be tetrakis(dimethylamido) zirconium, tetrakis(diethylamido) zirconium or tetrakis(ethylmethylamido) zirconium or adducts or hydrates thereof.

The zirconium precursor may be zirconium (IV) iso-propoxide, zirconium (IV) tert-butoxide, tetrakis(2-methyl-2-methoxypropoxy) zirconium, bis(iso-propoxy)bis(2-methyl-2-methoxypropoxy) zirconium or bis(tert-butoxy)bis(2-methyl-2-methoxypropoxy) zirconium or adducts or hydrates thereof.

The zirconium precursor may be ZrCl₄ or ZrBr₄.

The strontium precursor may be a strontium (II) precursor. The strontium precursor may be a strontium halide, strontium fl-diketonate, strontium alkoxide (such as iso-propoxide or tert-butoxide), dialkylamino strontium complex, alkylamino strontium complex, silylamido strontium complex, cyclopentadienyl strontium complex or strontium nitrate.

The strontium of the strontium precursor may have one or more (for example four) organic ligands which may be the same or different selected from the group of organic ligands defined by formulae (XIV) to (XVI) (preferably one of formulae (XIV) to (XVI)) as follows:

[R³⁰C(O)—CH—C(O)R³¹]⁻ (XVI)

(wherein each of R³⁰ and R³¹ which may be the same or different is an optionally fluorinated, linear or branched C₁₋₁₂ alkyl group);

[X(R³²)_{w}(R³³)_{y}(R³⁴)_{z}] (XV)

(wherein X is a heteroatom;

R³² is H or an optionally fluorinated, linear or branched C₁₋₁₂ alkyl group optionally substituted by one or more alkoxy, amino, alkylamino or dialkylamino groups or a (SiR³⁵)₂ or (SiR³⁵)₃ group;

R³³ is H or an optionally fluorinated, linear or branched C₁₋₁₂ alkyl group optionally substituted by one or more alkoxy, amino, alkylamino or dialkylamino groups or a (SiR³⁶)₂ or (SiR³⁶)₃ group;

R³⁴ is H or an optionally fluorinated, linear or branched C₁₋₁₂ alkyl group optionally substituted by one or more alkoxy, amino, alkylamino or dialkylamino groups or a (SiR³⁷)₂ or (SiR³⁷)₃ group;

each of R³⁵, R³⁶ and R³⁷ is independently H or a linear or branched C₁₋₁₂ alkyl, C₆₋₁₂ aryl, C₃₋₁₂ allyl or C₃₋₁₂ vinyl group optionally substituted by one or more alkoxy, amino, alkylamino or dialkylamino groups;

w is an integer of 1 or 2;

z is an integer of 0 or 1; and

y is an integer of 0 or 1);

[Cp] (XVI)

(wherein Cp denotes a single or fused cyclopentadiene moiety optionally ring-substituted partially or fully by one or more of the group consisting of an optionally substituted, acyclic or cyclic, linear or branched alkyl, alkenyl, aryl, alkylaryl, aralkyl or alkoxy group or a thio, amino, cyano or silyl group).

Preferably the strontium of the strontium precursor has two organic ligands selected from the group of organic ligands defined by formulae (XIV) to (XVI) (preferably one of formulae (XIV) to (XVI)).

Preferably the ligand of formula (XIV) is an optionally methylated and/or optionally fluorinated (eg optionally tri- or hexa-fluorinated) acetylacetonato, heptanedionato or octanedionato ligand. For example, the ligand of formula (XIV) may be a 1,1,1,5,5,5-hexafluoropentane-2,4-dionato, 6,6,7,7,8,8,8 -heptafluoro-2,2-dimethyl-3,5-octanedionato or 2,2,6,6-tetramethyl-3,5-heptanedionato ligand.

Preferably either or both of R³⁰ and R³¹ are trifluorinated or hexafluorinated.

Preferably R³⁰ is a C₁₋₆ perfluoroalkyl. Preferably R³¹ is a C₁₋₆ perfluoroalkyl.

Preferably X is O. Particularly preferably X is O, y is 0, z is 0, w is 1 and R³² is an optionally fluorinated, linear or branched C₁₋₁₂ alkyl group optionally substituted by one or more alkoxy, amino, alkylamino or dialkylamino groups. For example, the ligand of formula (XV) may be a hexafluoroisopropoxy, 2-dimethylaminoethanolate, 2-methoxyethanolate or 1-methoxy-2-methyl-2-propanolate ligand.

Preferably X is N. Particularly preferably X is N, y is 1, w is 1, z is 1 and each of R³², R³³ and R³⁴ is independently H or an optionally fluorinated, linear or branched C₁₋₁₂ alkyl group optionally substituted by one or more alkoxy, amino, alkylamino or dialkylamino groups.

Preferably each of R³², R³³ and R³⁴ is independently methyl, ethyl, propyl, butyl or pentyl, particularly preferably methyl, propyl or butyl, more preferably n-butyl, tert-butyl, isopropyl or ethyl.

Preferably the ligand of formula (XVI) is a cyclopentadienyl, indenyl, fluorenyl, pentamethylcyclopentadienyl or triisopropylcyclopentadienyl ligand, particularly preferably a cyclopentadienyl or indenyl ligand.

The strontium of the strontium precursor may have one or two ligands of formula (XVI). Preferably the strontium of the strontium precursor has two ligands of formula (XVI). The cyclopentadiene moieties of the two ligands of formula (XVI) may be bridged. The bridge may be a substituted or unsubstituted C₁₋₆-alkylene group which is optionally interrupted by a heteroatom (such as O, Si, N, P, Se or S). The cyclopentadiene moieties of the two ligands of formula (XVI) may be the same or different. Preferably each of the cyclopentadiene moieties of the two ligands of formula (XVI) is cyclopentadienyl or indenyl. Preferably the cyclopentadiene moieties of the two ligands of formula (XVI) are cyclopentadienyl and indenyl respectively.

Preferably in a strontium precursor the (or each) ligand of formula (XVI) is a cyclopentadienyl ligand of formula (XVII)

[C₅(R³⁸)ₘH₅₋ₘ] (XVII)

(wherein m is an integer in the range 0 to 5 and

each R³⁸ which may be the same or different is selected from the group consisting of a C₁₋₁₂ alkyl, C₁₋₁₂ alkylamino, C₁₋₁₂ dialkylamino, C₁₋₁₂ alkoxy, C₃₋₁₀ cycloalkyl, C₂₋₁₂ alkenyl, C₇₋₁₂ aralkyl, C₇₋₁₂ alkylaryl, C₆₋₁₂ aryl, C₅₋₁₂ heteroaryl, C₁₋₁₀ perfluoroalkyl, silyl, alkylsilyl, perfluoroalkylsilyl, triarylsilyl and alkylsilylsilyl group).

Preferably the (or each) R³⁸ group is methyl, ethyl, propyl (eg isopropyl) or butyl (eg tert-butyl). Particularly preferably each R³⁸ group is methyl.

The strontium precursor may be strontium nitrate.

The strontium precursor may be bis(1,1,1-trifluoropentane-2,4-dionato) strontium, bis(1,1,1,5,5,5-hexafluoropentane-2,4-dionato) strontium, bis(2,2,6,6-tetramethyl-3,5-heptanedionato) strontium or bis(6,6,7,7,8,8,8-heptafluoro-2,2-dimethyl-3,5-octanedionato) strontium or adducts or hydrates thereof.

The strontium precursor may be strontium (C₅(CH₃)₅)₂, bis((tert-Bu)₃cyclopentadienyl) strontium or bis(n-propyltetramethylcyclopentadienyl) strontium or adducts or hydrates thereof.

The strontium precursor may be bis[N,N,N′,N′,N″-pentamethyldiethylenetriamine] strontium, [tetramethyl-n-propylcyclopentadienyl] [N,N,N′,N′,N″-pentamethyldiethylenetriamine] strontium or [Oisopropyl] [indenyl] strontium or adducts or hydrates thereof.

In addition to one or more of the ligands mentioned hereinbefore, the metal in a precursor may have one or more additional ligands selected from anionic ligands, neutral monodentate or multidentate adduct ligands and Lewis base ligands. The metal may have 1 to 4 (eg two) additional ligands. For example, the (or each) additional ligand may be a β-diketonate (or a sulfur or nitrogen analogue thereof), halide, amide, alkoxide, carboxylate, substituted or unsubstituted C₁₋₆-alkyl group (which is optionally interrupted by a heteroatom such as O, Si, N, P, Se or S), benzyl, carbonyl, aliphatic ether, thioether, polyether, C₁₋₁₂ alkylamino, C₃₋₁₀ cycloalkyl, C₂₋₁₂ alkenyl, C₇₋₁₂ aralkyl, C₇₋₁₂ alkylaryl, C₆₋₁₂ aryl, C₅₋₁₂ heteroaryl, C₁₋₁₀ perfluoroa silyl, alkylsilyl, perfluoroalkylsilyl, triarylsilyl, alkylsilylsilyl, glyme (such as dimethoxyethane, diglyme, triglyme or tetraglyme), cycloalkenyl, cyclodienyl, cyclooctatetraenyl, alkynyl, substituted alkynyl, diamine, triamine, tetraamine, phosphinyl, carbonyl, dialkyl sulfide, vinyltrimethylsilane, allyltrimethylsilane, arylamine, primary amine, secondary amine, tertiary amine, polyamine, cyclic ether or pyridine aryl group. The additional ligand may be pyridine, toluene, tetrahydrofuran, bipyridine, a nitrogen-containing multidentate ligand (such as N,N,N′,N′,N″-pentamethyldiethylenetriamine (PMDETA) or N,N,N′,N′-tetramethylethylenediamine) or a Schiff base. The neutral monodentate or multidentate adduct ligand may derived from a solvent (eg tetrahydrofuran).

Preferred adduct ligands are dimethoxyethane, tetrahydrofuran, tetrahydropyran, diethylether, dimethoxymethane, diethoxymethane, dipropoxymethane, 1,2-dimethoxyethane, 1,2-diethoxyethane, 1,2-dipropoxyethane, 1,3-dimethoxypropane, 1,3-dipropoxypropane, 1,2-dimethoxybenzene, 1,2-diethoxybenzene and 1,2-dipropoxybenzene.

The precursor may be dissolved, dispersed or suspended in a solvent such as an aliphatic hydrocarbon or aromatic hydrocarbon (eg xylene, toluene, benzene, 1,4-tertbutyltoluene, 1,3-diisopropylbenzene, tetralin or dimethyltetralin) optionally together with a stabilizing agent (eg a Lewis-base ligand), an amine (eg octylamine, NN-dimethyldodecylamine or dimethylaminopropylamine), an aliphatic or cyclic ether (eg tetrahydrofuran), a glyme (eg diglyme, triglyme, tetraglyme), a C₃₋₁₂ alkane (eg hexane, octane, decane, heptane or nonane) and a tertiary amine.

Unless specified otherwise, the term alkyl used herein may be a linear or branched, acyclic or cyclic, C₁₋₁₂ alkyl and includes methyl, ethyl, propyl, isopropyl, n-butyl, tent-butyl, pentyl, isopentyl, hexyl, heptyl, octyl, nonyl, decyl, undecyl, dodecyl, cyclopropyl, cyclobutyl, cyclopentyl and cyclohexyl. Preferably each group C₁-₁₂ alkyl mentioned herein is preferably C₁₋₈ alkyl, particularly preferably C₁₋₆ alkyl.

Unless specified otherwise, the term aryl used herein may be a substituted, monocyclic or polycyclic C₆₋₁₂ aryl and includes optionally substituted phenyl, naphthyl, xylene and phenylethane.

The present invention will now be described in a non-limitative sense with reference to Examples.

The present invention will now be described in a non-limitative sense with reference to the Examples and accompanying Figures in which:

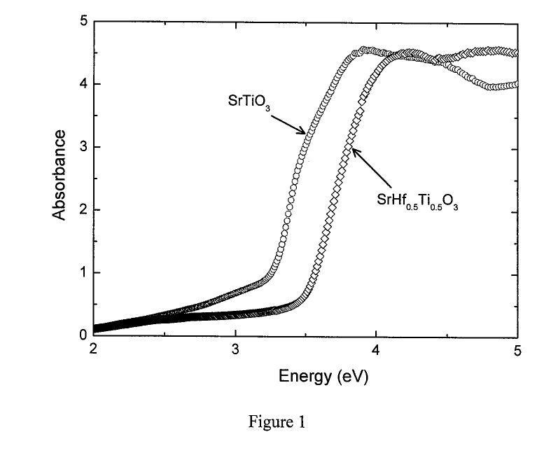

FIG. 1: Diffuse reflectance spectra of SrTiO₃ and SrHf_{0.5}Ti_{0.5}O₃ powders. The spectra were converted from reflection to absorbance using the Kubelka-Munk function and the optical band gap energy was then calculated by linear extrapolation of the absorption edge;

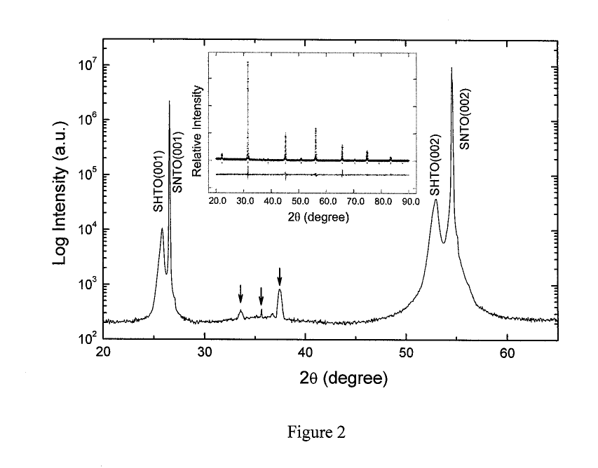

FIG. 2: Main figure shows XRD pattern of SrHf_{0.5}Ti_{0.5}O₃ film deposited on a (001) Nb—SrTiO₃ substrate. Peaks from the substrate are marked by arrows. The inset shows the Rietveld fit of powder XRD data from bulk SrHf_{0.5}Ti_{0.5}O₃ (space group Pm-3m, a=4.008±0.0002 Å) at room temperature. Observed data (crosses) and calculated data (solid line) are shown at top, reflection tick marks and refinement difference profile shown below;

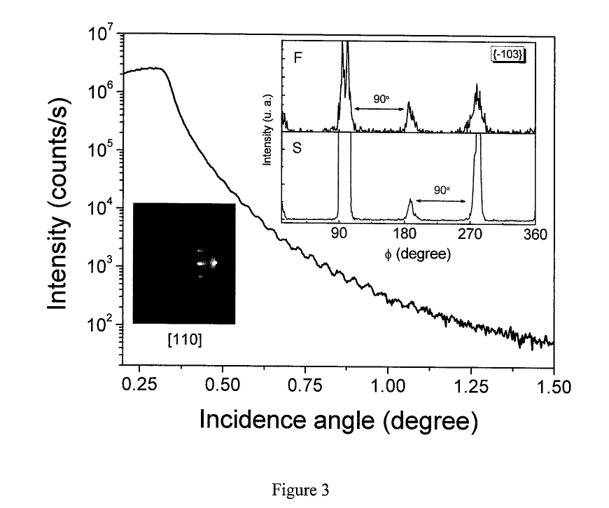

FIG. 3: Main figure shows XRR curve for the SrHf_{0.5}Ti_{0.5}O₃ film grown on Nb—SrTiO₃ substrate. Upper inset shows XRD Φ-scans recorded around the (−103) reflection of Nb—SrTiO₃ (S) and SrHf_{0.5}Ti_{0.5}O₃ (F). Lower insert shows the final RHEED image of the SHTO film along the [110] directions;

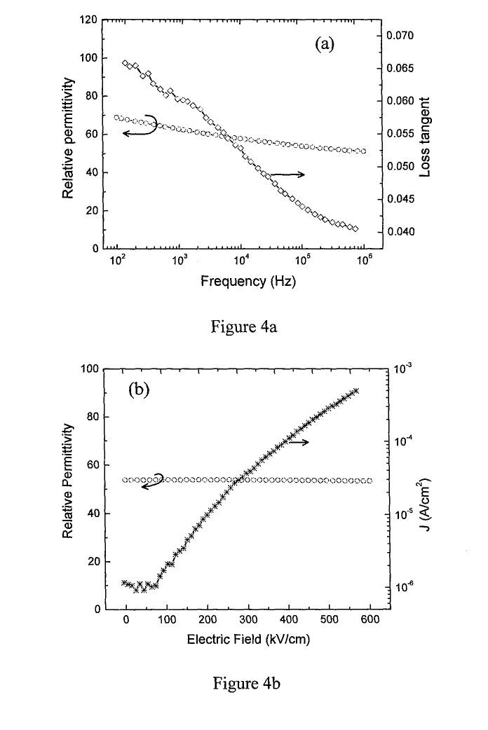

FIG. 4: The relative permittivity (circles) and loss tangent (squares) dependence on the measurement frequency are shown in FIG. 4(a). FIG. 4(b) shows leakage current density (stars) and the relative permittivity (circles) of the 96 nm thick SrHf_{0.5}Ti_{0.5}O₃ film (at 100 kHz) as a function of applied electric field;

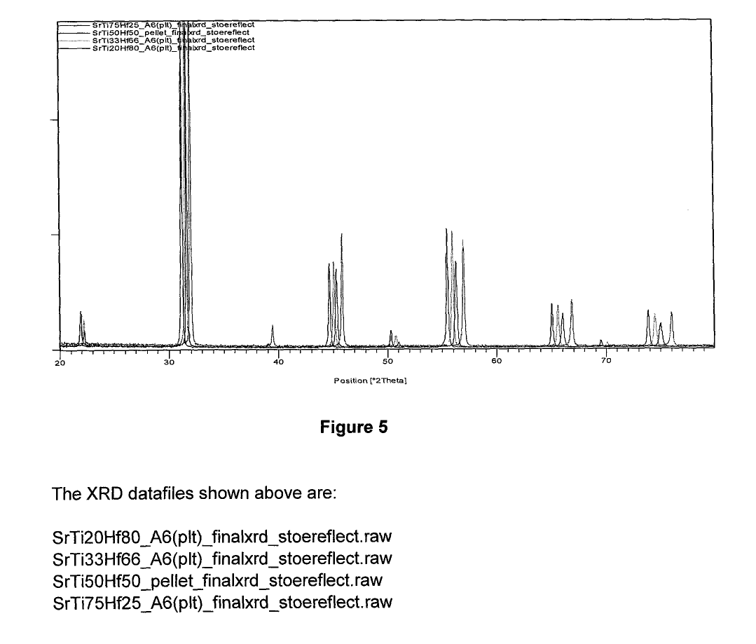

FIG. 5: XRD patterns for (x)SrTiO₃-(1−x)SrHfO₃ samples;

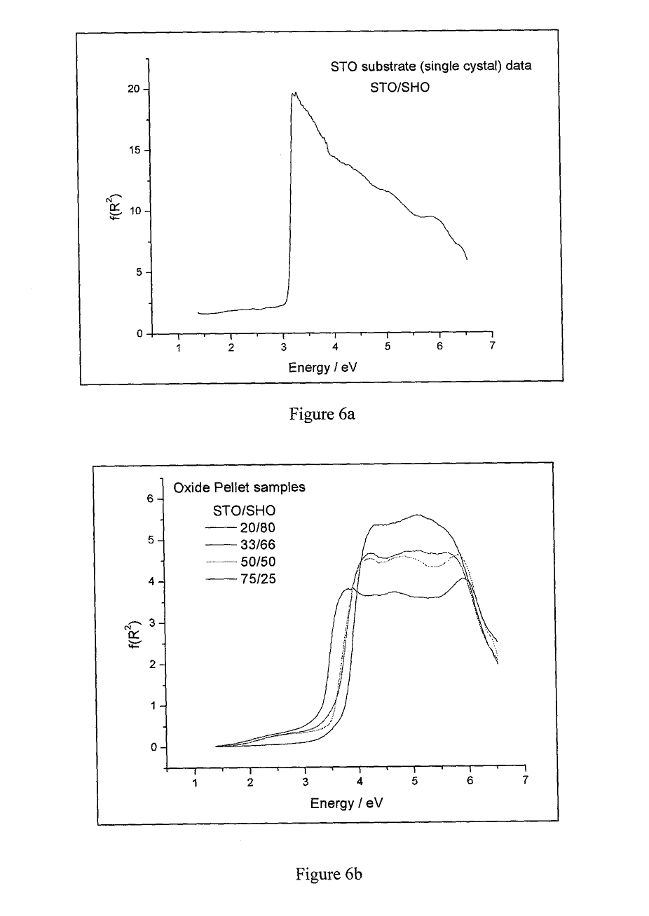

FIG. 6a: Band gap values obtained from measurements on a single crystal Nb—SrTiO₃ (001) substrate;

FIG. 6b: UV/vis measurements taken to determine the band gaps of the bulk samples;

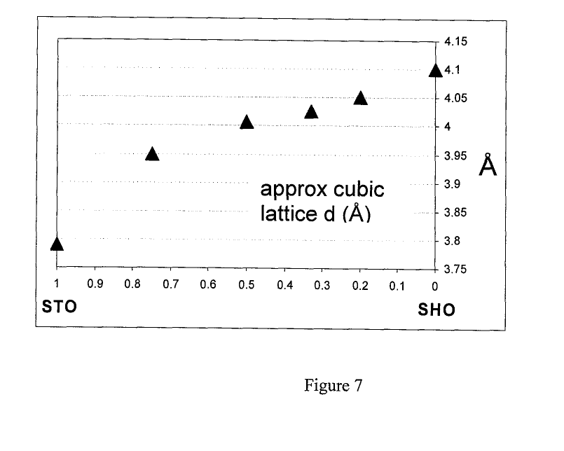

FIG. 7: Lattice values for (x)SrTiO₃-(1−x)SrHfO₃;

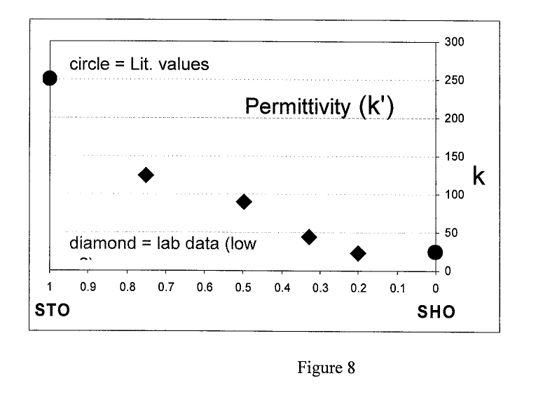

FIG. 8: Permittivity values for (x)SrTiO₃-(1−x)SrHfO₃; and

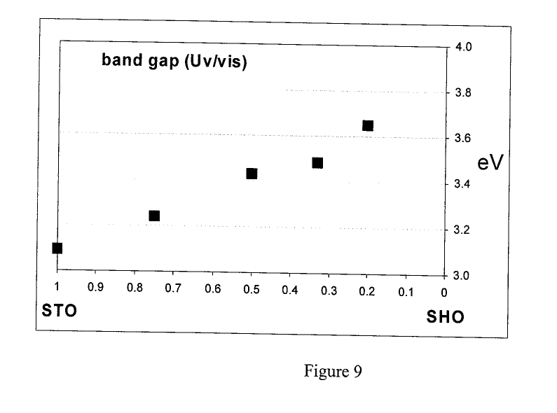

FIG. 9: Band gap values for (x)SrTiO₃-(1−x)SrHfO₃.

### EXAMPLE 1

Experimental

Bulk samples of SrHf_{0.5}Ti_{0.5}O₃ and SrTiO₃ were synthesized by the solid state reaction of reagent grade SrCO₃, HfO₂, and TiO₂ precursors. A stoichiometric mixture of the precursors was initially ball milled in ethanol with yttria-stabilized zirconia for 5 hrs. Powder calcination was performed by sequential 12 hr firings at 1000° C., 1300° C., 1400° C., and 1500° C. with grindings between firings to achieve phase homogeneity. Dense pellets suitable for physical measurements and for use as PLD targets were obtained by sintering isostatically pressed discs of calcined powder for 12 hrs at 1550° C. SrHf_{0.5}Ti_{0.5}O₃ films were deposited on (001) Nb—SrTiO₃ (Nb 0.5 wt %, PI-KEM Ltd) single crystal conducting substrates by PLD (Neocera) using a 248 nm KrF Lambda Physik excimer laser. Growth was monitored with a double-differentially pumped STAIB high pressure reflection high energy electron diffraction (RHEED) system. The SrHf_{0.5}Ti_{0.5}O₃ films were deposited at a substrate temperature of 750° C. in 100 mTorr pressure of oxygen. The laser was operated at a repetition rate of 4 Hz and a pulse energy of 260 mJ during deposition.

Results

The diffuse reflectance spectra of bulk SrHf_{0.5}Ti_{0.5}O₃ and SrTiO₃ powders are shown in FIG. 1. These spectra were obtained from a Perkin Elmer Lambda 650 S UV/Vis Spectrometer equipped with a Labsphere integrating sphere over the spectral range 190-900 nm using BaSO₄ reflectance standards. The optical band gaps of SrTiO₃ and SrHf_{0.5}Ti_{0.5}O₃ are 3.15 and 3.47 eV respectively. The band gap of SrHf_{0.5}Ti_{0.5}O₃ is larger than that of pure SrTiO₃ and smaller than the 6.2 eV of SrHfO₃ (see M. Sousa et al, J. Appl. Phys. 102, 104103 (2007)). This demonstrates that the partial substitution of Hf for Ti in SrTiO₃ can increase the band gap.

FIG. 2 shows the X-ray diffraction (XRD) pattern of the SrHf_{0.5}Ti_{0.5}O₃ films (collected on a PANalytical X-Pert diffractometer with an X-Celerator detector and Co K_{α1} radiation). Peaks corresponding to both the SrHf_{0.5}Ti_{0.5}O₃ film and Nb—SrTiO₃ substrate (with lattice constant c=3.905 Å) are visible. The (00l) peaks from the SrHf_{0.5}Ti_{0.5}O₃ film confirm the highly oriented in-plane epitaxial growth as deposited on (001) Nb—SrTiO₃. The c-lattice constant of the SrHf_{0.5}Ti_{0.5}O₃ film determined by XRD is 4.014±0.0002 Å. This agrees well with the structural parameters obtained for bulk SrHf_{0.5}Ti_{0.5}O₃ (cubic space group Pm-3m with a=4.008±0.0002 Å) as determined by Rietveld analysis of XRD data for the bulk material (shown as an inset in FIG. 2).

The X-ray reflectivity (XRR) measurement of the SrHf_{0.5}Ti_{0.5}O₃ film (FIG. 3) shows regular oscillations of weak amplitude whose separation corresponds to a thickness of 96.2±2 nm (performed on a Philips X'Pert Powder MPD diffractometer with an Eulerian cradle as a Prefix attachment and Cu K_{α1} radiation). The evaluation of the in-plane crystallography, as measured by Φ-scans of the (−103) off-axis reflection is shown in the upper insert of FIG. 3. The Φ-scans reveal the epitaxial relationship between the SrHf_{0.5}Ti_{0.5}O₃ film and Nb—SrTiO₃ substrate. The fourfold symmetry of the film is confirmed by four reflections at 90° intervals. The large full widths at half maximum (FWHM) of the Φ-reflections and their weak intensity are explained by the wide degree of in-plane texture. During the SrHf_{0.5}Ti_{0.5}O₃ film deposition process, high quality RHEED oscillations could not be obtained at the high (100 mTorr) oxygen pressure used in processing. However, the RHEED pattern of the final film shows well-ordered bright streaks (lower insert of FIG. 3) showing that the SrHf_{0.5}Ti_{0.5}O₃ film is well crystallized with a smooth surface.

The 0.5 wt % Nb (001) Nb—SrTiO₃ substrate is electrically conducting (Y. Huang et al, Chinese Sci. Bull. 51, 3 (2006); and H. B. Lu et al, Appl. Phys. Lett. 84, 5007 (2004)) with a resistivity of 4×10⁻⁴ Ω·cm. Circular Au contact electrodes (ø=290 μm) with a separation space of 1 mm were sputtered onto the SrHf_{0.5}Ti_{0.5}O₃ films. The dielectric permittivity and leakage current density of the films were measured at room temperature (293 K) using an LCR Agilent E4980A meter (over the frequency range 20-2 MHz and bias voltage range ±40V). All the measurements were carried out at room temperature (293 K).

The frequency-dependence of the relative permittivity and loss tangent of the SrHf_{0.5}Ti_{0.5}O₃ film is shown in FIG. 4(a). At 10 kHz, the relative permittivity of the film is 62.8, which is much larger than the value of 35 reported for SrHfO₃ (see Sousa [supra]). The loss tangent of the SrHf_{0.5}Ti_{0.5}O₃ film at 10 kHz is less than 0.07 which compares favorably with HfO₂ (see S.-W. Jeong et al, Thin Solid Films 515, 526 (2007)). The performance of the SrHf_{0.5}Ti_{0.5}O₃ film (at 100 kHz) as a function of the applied electric field is shown in FIG. 4(b). The relative permittivity of the SrHf_{0.5}Ti_{0.5}O₃ film changes by only 0.9% for applied electric fields up to 600 kV/cm showing stability under external electric fields (see Z. C. Quan et al, Thin Solid Films 516, 999 (2008); and W. F. Qin et al, J. Mater. Sci. 42, 8707 (2007)).

The leakage current density (J) at 600 kV/cm is 4.63×10⁻⁴ A/cm² which is comparable with dielectric materials such as HfO₂ (see S W Jeong [supra]; and B. D. Ahn et al, Mater. Sci. Semicon. Process. 9, 6 (2006)) but larger than for a SrHfO₃ film on TiN (see G Lupina et al, Appl. Phys. Lett. 93, 3 (2008)).

Conclusion

SrHf_{0.5}Ti_{0.5}O₃ films with a band gap of 3.47 eV have been deposited onto Nb—SrTiO₃ substrates at 750° C. in 100 mTorr of oxygen. The resulting epitaxial film has a relative permittivity of 62.8 with a low loss tangent of 0.07, together with low leakage current density and excellent stability under high applied electric fields. This demonstrates the feasibility of combining high permittivity and band gap energy enhancement via Hf substitution for Ti in SrTiO₃. SrHf_{0.5}Ti_{0.5}O₃ is therefore a promising high-k gate dielectric candidate material for future generations of silicon-based integrated circuits.

### EXAMPLE 2

Introduction

Bulk ceramic samples of compositions in the (x)SrTiO₃-(1−x)SrHfO₃ solid solution were made in order to compare properties (lattice constant, dielectric permittivity and band gap) with those of PLD thin films.

Synthesis

Powder samples were made by solid state reaction of SrCO₃, HfO₂, and TiO₂ precursors. Powders were initially ball milled to ensure good mixing and then hand ground between firings. Calcination was performed at temperatures increasing from 1000° C. to 1500° C. Sintering of isostatically pressed pellets was performed at 1550° C.

Results

Four compositions were made with the values x=0.75, 0.50, 0.33 and 0.20. Table 1 below gives the lattice constant, dielectric constant and band gap of the bulk SrHf₁₋ₓTiₓO₃(0≦x≦1) powders prepared according to this Example.

XRD of the powders and of sintered pellet surfaces (using the STOE transmission) confirmed single phase compositions in the SrTiO₃—SrHfO₃ series. FIG. 5 shows overlaying XRD patterns for the samples. The lattice expands (peaks move towards lower 2θ) with increasing Hf content.

Profile fits of the above patterns have been performed to determine approximate lattice values. The data were fit to a cubic Pm-3m space group. This is the structure of SrTiO₃. However SrHfO₃ has a small bulk orthorhombic distortion (Pnma). For these samples and the STOE resolution, no evidence of orthorhombic splitting was observed in the compositions. The determined values are listed in Table 1 below.

The lattice value for SrHfO₃ is a pseudo cubic approximation of the true but only slightly distorted subtle orthorhombic cell. In general, the unit cell expands nearly linearly with additional Hf content. This trend can be observed in FIG. 7.

The dielectric k′ value of the bulk pellet samples was measured at ambient temperature and 1 kHz using Solatron equipment. The obtained capacitance values were normalized to the sample dimensions. It is observed that the permittivity k′ value decreases with greater Hf content. The measured values are listed in Table 1 below and plotted in FIG. 8. When compared to a linear extrapolation between the reported literature values for SrHfO₃ and SrTiO₃, the measured bulk values are slightly low. This is likely to be a consequence of the non-ideal density of the sintered pellets. The density of the samples is estimated at ˜85-90%.

UV/vis measurements were taken to determine the band gaps of the bulk samples. These data are shown in FIG. 6b. Band gap values for SrTiO₃ were obtained from measurements on a single crystal Nb—SrTiO₃ (001) substrate (data shown in FIG. 6a). While the shape and absolute intensity measured for the absorption spectrum of bulk vs single crystal samples is different, the extrapolated band gap values agree well. These values are listed in Table 1 below and plotted in FIG. 9.

The band gap increases linearly with added Hf content. The measured SrTiO₃ value agrees well with the literature. However several literature reports cite a band gap value for SrHfO₃ of 5-6 eV. Based on the linear trend in FIG. 9 a SrHfO₃ band gap of approximately 4 eV might be expected. The reasons for this discrepancy are unclear. It is possible that the system will exhibit a non-linear increase in band gap at compositions nearer to SrHfO₃. Alternatively previously reported values may be overestimated.

TABLE 1
Lattice constant, dielectric constant and band gap of
bulk SrHf₁₋ₓTiₓO₃ (0 ≦ x ≦ 1)

| | (x) | lattice (Å) | k′ | Band Gap (ev) |
|---|---|---|---|---|
| STO | 1.00 | 3.79 | 205* | 3.09 |
| | 0.75 | 3.95 | 125 | 3.24 |
| | 0.50 | 4.01 | 90 | 3.43 |
| | 0.33 | 4.03 | 45 | 3.48 |
| | 0.20 | 4.05 | 23 | 3.65 |
| SHO | 0.00 | 4.10 | 25* | 5-6* |

*= Literature values

### EXAMPLE 3

### Process for Preparing Sr(Hf₁₋ₓTiₓ)O₃

A film of the mixed oxide Sr(Hf₁₋ₓTiₓ)O₃ is prepared on a substrate in a reactor (OpaL ALD (Oxford Instruments Limited)) using the following precursors:

Precursor P1: bis(2,2,6,6-tetramethylheptane-3,5-dionato) strontium (source temperature 170° C.)

Precursor P2: bis(methyl-η₅-cyclopentadienyl)methoxymethyl hafnium (source temperature 80° C.)

Precursor P3: Titanium (IV) isopropoxide (source temperature 50° C.).

The reactor is maintained at a pressure of 1-2 mbar and the temperature of the substrate is 300° C.

The purge gas is 200 sccm argon.

The duration of the steps in each deposition cycle for n cycles is as follows:

{[P1, 2 s/purge 2 s/H₂O, 0.5 s/purge 3.5 s], [P2, 2 s/purge 2 s/H₂O, 0.5 s/purge 3.5s]ₓ, [P3, 2 s/purge 2 s/H₂O, 0.5 s/purge 3.5 s]_{y}}ₙ (x:y ˜1:1 to 1:3)

### EXAMPLE 4

### Process for Preparing Sr(Zr₁₋ₓTiₓ)O₃

A film of the mixed oxide Sr(Zr₁₋ₓTiₓ)O₃ is prepared on a substrate in a reactor (OpaL ALD (Oxford Instruments Limited)) using the following precursors:

Precursor P1: bis(2,2,6,6-tetramethylheptane-3,5-dionato) strontium (source temperature 170° C.)

Precursor P2: bis(methyl-η5-cyclopentadienyl) methoxymethyl zirconium (source temperature 70° C.)

Precursor P3: Titanium (IV) isopropoxide (source temperature 50° C.).

The reactor is maintained at a pressure of 2 mbar and the temperature of the substrate is 325° C.

The purge gas is 300 sccm argon.

The duration of the steps in each deposition cycle for n cycles is as follows:

{[P1, 2 s/purge 2 s/H₂O, 0.5 s/purge 3.5 s], [P2, 2 s/purge 2 s/H₂O, 0.5 s/purge 3.5 s]ₓ, [P3, 2 s/purge 2 s/H₂O, 0.5 s/purge 3.5 s]_{y}}ₙ (x:y˜1:1 to 1:3)

### EXAMPLE 5

### Process for Preparing Sr(Hf₁₋ₓTiₓ)O₃

A film of the mixed oxide Sr(Hf₁₋ₓTiₓ)O₃ is prepared on a substrate in a reactor (OpaL ALD (Oxford Instruments Limited)) using the following precursors:

Precursor P1: Sr(tert-Bu₃Cp)₂

Precursor P2: Hf(HNEtMe)₄

Precursor P3: Ti(OMe₃)₄

The reactor is maintained at a pressure of 1-2 mbar and the temperature of the substrate is 275° C. The purge gas is 200 sccm argon.

The duration of the steps in each deposition cycle for n cycles is as follows:

{[P1, is/purge 2 s/H₂O, 0.5 s/purge 5 s], [P2, is/purge 2 s/H₂O, 0.5 s/purge 5 s]ₓ, [P3, 1 s/purge 2 s/H₂O, 0.5 s/purge 5 s]_{y}}ₙ (x:y˜1:1 to 1:3).

1. A mixed metal oxide of formula:
SrM₁₋ₓTiₓO₃
wherein x is 0<x<1; and
M is Hf or Zr.

2. The mixed metal oxide as claimed in claim 1 wherein x is 0.01<x<0.99.

3. The mixed metal oxide as claimed in claim 1 wherein the strontium-hafnium-titanium oxide exhibits a dielectric constant of greater than 35.

4. The mixed metal oxide as claimed in claim 1 which exhibits a band gap of 3.10 eV or more.

5. The mixed metal oxide as claimed in claim 1, which is substantially monophasic.

6. The mixed metal oxide as claimed in claim 1, wherein M is Hf.

7. A composition comprising a mixed metal oxide as defined in claim 1, and one or more oxides of one or more of strontium, M and titanium.

8. A functional device comprising:
a substrate; and
an element fabricated on the substrate, wherein the element is composed of a mixed metal oxide or composition thereof having a formula:
SrM₁₋ₓTiₓO₃
wherein x is 0<x<1; and
M is Hf or Zr.

9. The functional device as claimed in claim 8 which is an electrical, electronic, magnetic, mechanical, optical or thermal device.

10. The functional device as claimed in claim 8 wherein the substrate is silicon.

11. The functional device as claimed in claim 8, which is a field effect transistor device, wherein the substrate is a substrate layer and the element is a gate dielectric fabricated on the substrate layer, wherein the field effect transistor further comprises:
a gate on the gate dielectric.

12. The functional device as claimed in claim 11 which is a MOSFET device.

13. The mixed metal oxide or composition thereof as defined in claim 1, used as a dielectric as or in an electrical, electronic, magnetic, mechanical, optical or thermal device.

14. A process for preparing a functional device as defined in claim 8, comprising:
exposing discrete volatilised amounts of a strontium precursor, a hafnium or zirconium precursor and a titanium precursor to the substrate in sequential exposure steps in a contained environment.

15. The functional device as claimed in claim 9 wherein the substrate is silicon.

16. The functional device as claimed in claim 9, which is a field effect transistor device, wherein the substrate is a substrate layer and the element is a gate dielectric fabricated on the substrate layer, wherein the field effect transistor further comprises:
a gate on the gate dielectric.

17. The functional device as claimed in claim 10, which is a field effect transistor device, wherein the substrate is a substrate layer and the element is a gate dielectric fabricated on the substrate layer, wherein the field effect transistor further comprises:
a gate on the gate dielectric.

18. A process for preparing a functional device as defined in claim 9, comprising:
exposing discrete volatilised amounts of a strontium precursor, a hafnium or zirconium precursor and a titanium precursor to the substrate in sequential exposure steps in a contained environment.

19. A process for preparing a functional device as defined in claim 10, comprising:
exposing discrete volatilised amounts of a strontium precursor, a hafnium or zirconium precursor and a titanium precursor to the substrate in sequential exposure steps in a contained environment.

20. A process for preparing a functional device as defined in claim 11, comprising:
exposing discrete volatilised amounts of a strontium precursor, a hafnium or zirconium precursor and a titanium precursor to the substrate in sequential exposure steps in a contained environment.

21. A process for preparing a functional device as defined in claim 12, comprising:
exposing discrete volatilised amounts of a strontium precursor, a hafnium or zirconium precursor and a titanium precursor to the substrate in sequential exposure steps in a contained environment.
